(19) United States
(12) Patent Application Publication
(10) Pub. No.: US 2014/0060608 A1
(43) Pub. Date: Mar. 6, 2014

(54) PHOTOVOLTAIC DEVICE AND METHOD OF MAKING

(71) Applicants: Jongwoo Choi, Latham, NY (US); Bastiaan Arie Korevaar, Schenectady, NY (US); Jinbo Cao, Rexford, NY (US)

(72) Inventors: Jongwoo Choi, Latham, NY (US); Bastiaan Arie Korevaar, Schenectady, NY (US); Jinbo Cao, Rexford, NY (US)

(73) Assignee: GENERAL ELECTRIC COMPANY, SCHENECTADY, NY (US)

(21) Appl. No.: 13/600,272

(22) Filed: Aug. 31, 2012

(51) Int. Cl. H01L 31/0216; H01L 31/042; H01L 31/18

(52) U.S. Cl. 136/244; 438/57; 136/256; 257/E31.004

(57) ABSTRACT

A photovoltaic device is presented. The device includes an intermediate layer disposed between an absorber layer and a back contact layer. The intermediate layer includes a metal or metalloid of Group 15 and oxygen. Method for making a photovoltaic device is also presented.

### BACKGROUND

The invention generally relates to photovoltaic devices. More particularly, the invention relates to improved back contacts for photovoltaic devices.

Photovoltaic (“PV”) devices or cells convert light directly into electricity. Photovoltaic devices are used in numerous applications, from small energy conversion devices for calculators and watches to large energy conversion devices for households, utilities, and satellites.

Thin film solar cells or photovoltaic devices typically include a plurality of semiconductor layers disposed on a transparent substrate, wherein one layer serves as a window layer and a second layer serves as an absorber layer. The window layer allows the penetration of solar radiation to the absorber layer, where the optical energy is converted to usable electrical energy. Cadmium telluride/cadmium sulfide (CdTe/CdS) heterojunction-based photovoltaic cells are one such example of thin films solar cells.

Cadmium telluride (CdTe) based solar cell devices typically demonstrate relatively low power conversion efficiencies, which may be attributed to a relatively low open circuit voltage (V_{oc}) in relation to the band gap of the material which is due, in part, to the low effective carrier concentration and short minority carrier lifetime in CdTe. The short minority carrier lifetime that is typically exhibited by thin film CdTe devices may be attributed to the high defect density that occurs when thin film CdTe is grown at relatively low temperatures (500-550° C.) using close-spaced sublimation (or CSS). The high defect density results in the presence of donor and acceptor states that offset each other, resulting in an effective carrier density in the 10¹¹ to 10¹⁵ per cubic centimeter (cc) range for CdTe.

Further issues with improving the cell efficiency of CdTe solar cells include the high work function of CdTe. The high work function of CdTe material is one of the major barriers in achieving a good Ohmic contact between the CdTe absorber layer and a back contact. P-type CdTe, typically, has a work function of about 5.5 electron-volt or above, depending on the concentration of the charge carriers or charge carrier density. No metal or alloy has such a high work function and hence it becomes difficult for metals and alloys to form a good Ohmic contact with the p-type CdTe. The mismatch of work functions creates a barrier at the junction between a metal or alloy contact and the p-type CdTe layer. This barrier hinders the transportation of a majority of the charge carriers and thus brings down performance of the cell.

One approach to improve the back-contact barrier or resistance includes increasing the carrier concentration in the regions near the contact points of the CdTe layer and the back contact layer, wherein the back contact layer is a metal layer. For example, for a p-type CdTe material, increasing the carrier concentration amounts to increasing the p-type carriers in the CdTe material to form a “p+ layer” on the backside of the CdTe layer, which is in contact with the back contact layer. However, typical methods employed to form the p+ layers may pose drawbacks such as, for example, diffusion of metal through CdTe causing degradation and environmental concerns.

Thus, there is a need to provide improved back contact layer configuration to provide improved interfaces and to minimize recombination of electron/hole pairs at the back contact. Further, there is a need to provide cost-effective photovoltaic devices having improved back contact to provide the desired power conversion efficiencies.

### BRIEF DESCRIPTION OF THE INVENTION

Embodiments of the invention are directed towards a back contact layer for a photovoltaic device and a method for forming the same.

In one embodiment, a device includes an intermediate layer disposed between an absorber layer and a back contact layer. The intermediate layer includes a metal or metalloid of Group 15, and oxygen. A photovoltaic module including a plurality of such devices is also presented.

One embodiment is a photovoltaic device including a window layer, an absorber layer disposed on the window layer, an intermediate layer disposed on the absorber layer, and a back contact layer disposed on the intermediate layer. The intermediate layer includes a metal or a metalloid of Group 15, and oxygen. The window layer includes cadmium sulfide, and the absorber layer includes cadmium telluride.

One embodiment is a method. The method includes disposing a layer comprising a metal or a metalloid of Group 15 on an absorber layer, and thermally processing the layer in an oxygen environment to form an intermediate layer. The intermediate layer includes the metal or the metalloid of Group 15, and oxygen.

### DRAWINGS

These and other features, aspects, and advantages of the present invention will become better understood when the following detailed description is read with reference to the accompanying drawings in which like characters represent like parts throughout the drawings, wherein:

FIG. 1 is a schematic of a photovoltaic device, in accordance with one embodiment of the invention;

FIG. 2 is a schematic of a photovoltaic device, in accordance with one embodiment of the invention;

FIG. 3 shows XPS depth profiles of an intermediate layer, in accordance with one embodiment of the invention;

FIG. 4 shows the performance parameters for photovoltaic devices, in accordance with some embodiments of the invention;

FIG. 5 shows the performance parameters for photovoltaic devices, in accordance with some embodiments of the invention.

### DETAILED DESCRIPTION

As discussed in detail below, some of the embodiments of the invention provide improved back contacts for photovoltaic devices. In one embodiment, the improved back contact includes an intermediate layer disposed between an absorber layer and a back contact layer. The intermediate layer includes a metal or a metalloid of Group 15, and oxygen. In certain embodiments, the intermediate layer includes antimony oxide. The layer may, in some embodiments, include other elements from Group 15, for example bismuth. In some embodiments, the intermediate layer may function as a p⁺-layer, and provides an improved interface (having low concentration of defect states) between the absorber layer and the back contact layer.

In one embodiment, the intermediate layer has a greater band gap as compared to the absorber layer. The intermediate layer may advantageously function as an electron reflector depending on the band alignment. In some embodiments, a combination of the intermediate layer and the absorber layer may provide for an improved back contact having minimal electron/hole pair recombination in thin film CdTe photovoltaic devices.

Approximating language, as used herein throughout the specification and claims, may be applied to modify any quantitative representation that could permissibly vary without resulting in a change in the basic function to which it is related. Accordingly, a value modified by a term or terms, such as “about”, is not limited to the precise value specified. In some instances, the approximating language may correspond to the precision of an instrument for measuring the value.

In the following specification and the claims, the singular forms “a”, “an” and “the” include plural referents unless the context clearly dictates otherwise.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable, or suitable. For example, in some circumstances, an event or capacity can be expected, while in other circumstances the event or capacity cannot occur—this distinction is captured by the terms “may” and “may be”.

The terms “transparent region” and “transparent layer” as used herein, refer to a region or a layer that allows an average transmission of at least 80% of incident electromagnetic radiation having a wavelength in a range from about 300 nm to about 850 nm As used herein, the term “disposed between” or “disposed on” refers to layers disposed directly in contact with each other or indirectly by having intervening layers there between, unless otherwise specifically indicated.

Fill factor (FF) in the context of solar cell technology is defined as a ratio (usually given as percent) of the actual maximum obtainable power to the theoretical (not actually obtainable) power. This is a parameter often used in evaluating the performance of solar cells. Typically, solar cells have fill factor up to about 0.85.

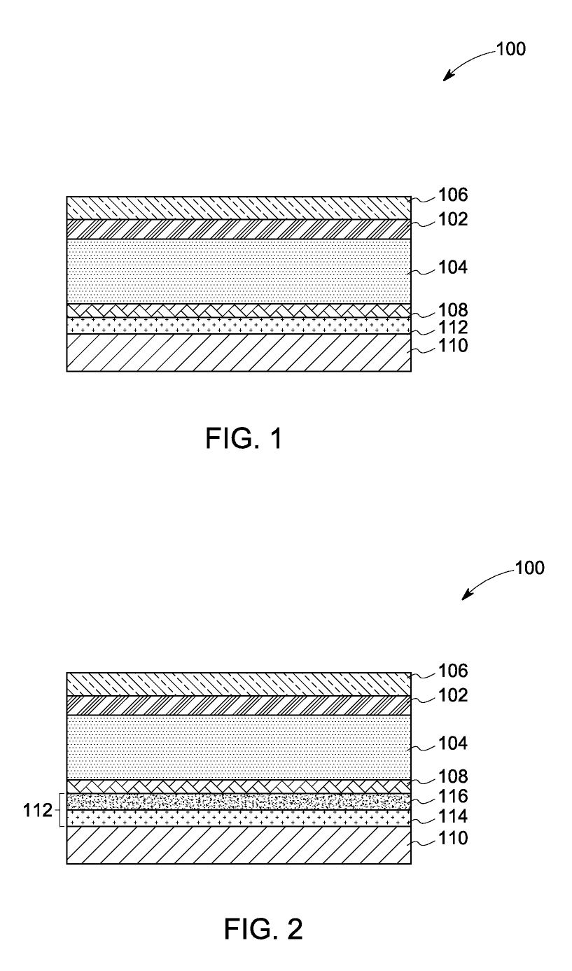

As discussed in detail below, some embodiments of the invention are directed to an improved back contact for a photovoltaic device. A photovoltaic device 100 according to one embodiment of the invention is illustrated in FIGS. 1-2. As shown in FIGS. 1-2, the photovoltaic device 100 includes an intermediate layer 102 disposed between an absorber layer 104 and a back contact layer 106, wherein the intermediate layer 102 includes a metal or a metalloid of Group 15, and oxygen. In some embodiments, a combination of the intermediate layer 102, and the back contact layer 106 may provide for an improved back contact in the photovoltaic device 100.

As indicated in FIGS. 1-2, in one embodiment, the photovoltaic device 100 further includes a window layer 108, wherein the absorber layer 104 is disposed on the window layer. In one embodiment, the photovoltaic device 100 further includes a transparent layer 112 and a support or substrate 110, wherein the transparent layer 112 is disposed on the substrate 110 and the window layer 108 is disposed on the transparent layer 112 to form the photovoltaic device 100. The transparent layer 112 includes an electrically conductive layer.

As discussed, the absorber layer 104 is disposed on a window layer 108, and the two layers may be doped with a p-type dopant or n-type dopant to form a hetero-junction. As used in this context, a hetero-junction is a semiconductor junction that is composed of layers of dissimilar semiconductor materials. These materials usually have non-equal band gaps. As an example, a hetero-junction can be formed by disposing a layer or region of one conductivity type material on a layer or region of opposite conductivity type material, e.g., a “p-n” junction. The term “conductivity-type material”, as used herein refers to a type of a doped semiconductor material. Those skilled in the art are familiar that a doped semiconductor may be n-type or p-type based on a dopant introduced to the semiconductor.

As illustrated in FIGS. 1-2, in such embodiments, the solar radiation enters from the substrate 110 and, after passing through the transparent layer 112 and the window layer 108, enters the absorber layer 104, where the conversion of electromagnetic energy of incident light (for instance, sunlight) to electron-hole pairs (that is, to free electrical charge) occurs. The electron-hole pairs generated in the absorber layer are separated by an internal field generated by the oppositely doped semiconductor layers, so as to create the photovoltaic current. In this manner, the device 100, when exposed to appropriate illumination, generates a photovoltaic current, which is collected by the electrically conductive layers 106 and 112, which are in electrical communication with appropriate layers of the device 100.

“Absorber layer”, as used herein, refers to a semiconductor layer wherein the electromagnetic radiation is absorbed and converted to electron-hole pairs. Typically, when solar radiation is incident on the photovoltaic device, electrons in the absorber layer are excited from a lower energy “ground state,” in which they are bound to specific atoms in the solid, to a higher “excited state,” in which they can move through the solid, as free electrons (charge carriers).

In one embodiment, a photoactive material is used for forming the absorber layer 104. Suitable photo-active materials for the absorber layer 104 include, but are not limited to, cadmium telluride (CdTe), cadmium zinc telluride (CdZnTe), cadmium sulfur telluride, cadmium selenium telluride, cadmium lead telluride, cadmium magnesium telluride (CdMgTe), and cadmium manganese telluride (CdMnTe), or combinations thereof. The above-mentioned photo-active semiconductor materials may be used alone or in combination. In one particular embodiment, the absorber layer 104 includes cadmium telluride (CdTe). In one particular embodiment, the absorber layer 104 includes p-type cadmium telluride (CdTe).

A “window layer” in a photovoltaic device is broadly defined as all the layers through which light passes before being absorbed in an absorber layer. The “window layer”, as used herein, refers to substantially transparent single layer or multiple layers that allow light to pass through to an absorber layer, and forms a hetero-junction with an absorber layer.

In one embodiment, the window layer 108 includes sulfur, oxygen, selenium, or combinations thereof. Non-limiting exemplary materials for the window layer 108 include cadmium sulfide (CdS), oxygenated cadmium sulfide (CdS:O), indium sulfide (In₂S₃), indium selenide (In₂Se₃), zinc sulfide (ZnS), zinc selenide (ZnSe), cadmium selenide (CdSe), cadmium sulfate, cadmium oxysulfate, zinc sulfate, zinc oxysulfate, zinc oxihydrate (Zn(OH)), or combinations thereof. Other examples may include indium sulfate, indium oxysulfate, or combinations thereof. In some embodiments, the window layer 108 includes cadmium sulfide (CdS). In a particular embodiment, the window layer 108 includes n-type CdS.

The above-mentioned semiconductor materials may be used alone or in combination. Further, these materials may be present in more than one layer, each layer having different type of semiconductor material or having combinations of the materials in separate layers.

In some embodiments, the absorber layer 104 includes a p-type semiconductor material. The absorber layer 104 may contain a suitable amount of a dopant to increase the efficiency of the device. In one embodiment, the absorber layer has an average carrier density varying between about 1×10¹³ per cubic centimeter (cc) and about 1×10¹⁵ per cubic centimeter (cc). As used herein, “carrier density” refers to the concentration of the majority charge carriers in a material. Holes represent majority charge carriers in p-type semiconductor material.

It is desirable that the absorber layer 106 has a heavily doped p-type surface (average carrier density≧1×10¹⁵ per cc) adjacent to a back contact layer 106. A heavily doped p-type surface of the absorber layer 106 may provide a good interface with a back contact layer 106. Higher carrier densities of the p-type surface may minimize the series resistance of the back contact layer 106, in comparison to other resistances within the device.

Typically, an absorber layer is sufficiently thick to absorb incident electromagnetic radiation. In one embodiment, the absorber layer 104 has a thickness in a range from about 0.5 micron to about 5 microns. In a particular embodiment, the absorber layer has a thickness in a range from about 1.5 microns to about 3 microns. The use of the intermediate layer 102 according to some embodiments of the invention advantageously provides for an improved interface at the back-side of the CdTe-layer, reducing the recombination rate at that interface. A low recombining back contact for photovoltaic devices may employ thin CdTe layers, such as, for example having a thickness in a range less than about 2 microns.

The thickness of the window layer 108 is typically desired to be minimized in a photovoltaic device to achieve high efficiency. In some embodiments, the thickness of the window layer 108 is between about 10 nanometers and about 100 nanometers. In certain embodiments, the thickness of the window layer is between about 30 nanometers and about 80 nanometers.

In some embodiments, the window layer 108, the absorber layer 104, or both layers contain oxygen. Without being bound by any theory, it is believed that oxygen introduction to the window layer 108 (for example CdS layer) provides high efficiency and improved device performance. In some embodiments, the amount of oxygen is less than about 25 atomic percent. In some instances, the amount of oxygen in the window layer 108 is between about 1 atomic percent to about 10 atomic percent. In some instances, for example in the absorber layer, the amount of oxygen is less than about 1 atomic percent. Moreover, the oxygen concentration within the window layer 108, the absorber layer 104, or both layers, may be substantially constant or compositionally graded across the thickness of the respective layer.

As noted earlier, the device 100 includes an intermediate layer 102 disposed between the absorber layer 104 and the back contact layer 106. In one embodiment, the intermediate layer 102 includes a metal or a metalloid of Group 15, and oxygen. The metal or metalloid of Group 15 may include arsenic (As), antimony (Sb), bismuth (Bi), or combinations thereof. Certain embodiments include antimony. In these instances, the intermediate layer 102 includes an oxide of antimony. Some other phases such as complex compounds (for example, CdSbₓTe_{y}O_{z}) may also be present. The formation of such oxides and complex compounds may provide an improved interface at the back contact. Without being bound by any theory, this improved interface at the back-contact may be due to passivation of defect states, for example Cd and/or Te interaction with Sb and oxygen.

Furthermore, the material of the intermediate layer 102 (oxides and complex compound) may have a band gap greater than the band gap of the material of the absorber layer 104 (for example, CdTe). In one embodiment, the band gap may be in a range from about 2.4 eV to about 5 eV. A greater band gap layer between the absorber layer 104 and the back contact layer 106 may function as an electron reflector depending on the band alignment. In some embodiments, the intermediate layer 102 may function as an electron reflector, especially if the mismatch in energy gap of the intermediate layer 102 and the absorber layer 104 is such that the conduction band level of the intermediate layer is significantly above that of the absorber layer. An “electron reflector” layer reflects electrons back to an absorber layer while it allows holes to tunnel through, which may help to improve V_{oc} of the device.

In some embodiments, the intermediate layer 102 may function as a p⁺-layer. A p⁺-layer as used herein refers to a semiconductor layer having an excess mobile p-type carrier or hole density compared to the p-type charge carrier or hole density in the absorber layer 104. In one embodiment, the p⁺-type semiconductor layer has a p-type carrier density in a range greater than about 1×10¹⁷ per cubic centimeter (cc). Higher carrier densities of the p⁺-type semiconductor layer may minimize the series resistance of the back contact layer, in comparison to other resistances within the device. In some embodiments, the intermediate layer 102 may further help in retarding impurity diffusion from a back contact side to a front contact, and/or sulfur diffusion from a front contact side.

In some embodiments, a combination of the intermediate layer 102 and the absorber layer 104 may provide for an improved back contact having minimal electron/hole pair recombination in thin film CdTe photovoltaic devices. The thickness of the intermediate layer 102 may or may not be uniform. In one embodiment, the average thickness of the intermediate layer may be in a range from about 1 nanometer to about 200 nanometers. In certain embodiments, the average thickness may range from about 10 nanometers to about 100 nanometers.

As indicated in FIGS. 1-2, the window layer 108 is disposed on a transparent layer 112 that is disposed on a support or substrate 110. In one embodiment, the transparent layer 112 includes an electrically conductive layer (sometimes referred to in the art as a front contact layer) 114 disposed on the substrate 110, as indicated in FIG. 2. In some embodiments, the window layer 108 is disposed directly on the electrically conductive layer 114. In an alternate embodiment, the transparent layer 112 includes an electrically conductive layer 114 disposed on the substrate 110 and an additional layer 116 interposed between the electrically conductive layer 114 and the window layer 108, as indicated in FIG. 2. In one embodiment, the transparent layer 112 has a thickness in a range from about 100 nanometers to about 600 nanometers.

In one embodiment, the electrically conductive layer 114 includes a transparent conductive oxide (TCO). Non-limiting examples of transparent conductive oxides include cadmium tin oxide (CTO), indium tin oxide (ITO), fluorine-doped tin oxide (SnO:F or FTO), indium-doped cadmium-oxide, cadmium stannate (Cd₂SnO₄ or CTO), doped zinc oxide (ZnO), such as aluminum-doped zinc-oxide (ZnO:Al or AZO), indium-zinc oxide (IZO), and zinc tin oxide (ZnSnOₓ), (Cd,Zn)₂SnO₄, or combinations thereof. Depending on the specific TCO employed and on its resistivity, the thickness of the electrically conductive layer 114 may be in a range of from about 50 nm to about 600 nm, in one embodiment.

The additional layer 116 (optional) is another transparent conductive oxide layer with higher resistance than that of TCO, and usually called as high resistance transparent (HRT) layer. In one embodiment, the thickness of the HRT layer 116 is in a range from about 10 nm to about 200 nm. Non-limiting examples of suitable materials for the HRT layer 116 include tin dioxide (SnO₂), zinc tin oxide (ZTO), zinc-doped tin oxide (SnO₂:Zn), zinc oxide (ZnO), indium oxide (In₂O₃), zinc stannate (Zn₂SnO₄), or combinations thereof.

In one embodiment, the substrate 110 is transparent over the range of wavelengths for which transmission through the substrate 110 is desired. In one embodiment, the substrate 110 may be transparent to visible light having a wavelength in a range from about 350 nm to about 1200 nm. In some embodiments, the substrate 110 includes a material capable of withstanding heat treatment temperatures greater than about 600° C., such as, for example, silica or borosilicate glass. In some other embodiments, the substrate 110 includes a material that has a softening temperature lower than 600° C., such as, for example, soda-lime glass or a polyimide. In some embodiments certain other layers may be disposed between the transparent layer 108 and the substrate 110, such as, for example, an anti-reflective layer, a down converting layer, or a barrier layer (not shown).

Any suitable metal having the desired conductivity and reflectivity may be selected as the back contact layer 106. Non-limiting examples of the metal for the layer 106 include gold, platinum, molybdenum, tungsten, tantalum, palladium, aluminum, chromium, nickel, copper, or silver. In certain embodiments, the metal contact includes copper (Cu). Another metal layer (not shown), for example, aluminum, may be disposed on the metal layer to assist with lateral conduction to the outside circuit. In some instances, the metal contact includes Cu/Au contact. In some instances, the metal contact may include Cu and Ni/Al. Some other examples for the back contact layer 106 may also include non-metallic contacts, such as graphite.

In one embodiment, a method of making a photovoltaic device 100, as illustrated in FIGS. 1-2, is provided. The method generally includes disposing a layer on the absorber layer 104, and thermally processing the layer in an oxygen environment for the formation of the intermediate layer 102. The back contact layer 106 is disposed on the intermediate layer after performing thermal processing step.

In some particular embodiments, a method for making a device is described. Referring to FIGS. 1-2, the method includes disposing a transparent layer 108 including an electrically conductive layer 112 on a substrate 110 by any suitable technique, such as sputtering, chemical vapor deposition, spin coating, spray coating, or dip coating. Referring to FIG. 2, in some embodiments, an optional HRT layer 114 may be deposited on the electrically conductive layer 112 using sputtering to form the transparent layer 108.

The method further includes disposing a window layer 108 on the electrically conductive layer 112 followed by disposing the absorber layer 104 on the window layer 108. A variety of deposition techniques are available for depositing the absorber layer 104 and window layer 108. Suitable techniques may include one or more of close-space sublimation (CSS), vapor transport method (VTM), chemical bath deposition (CBD), sputtering, electrochemical deposition (ECD), ion-assisted physical vapor deposition (IAPVD), radio frequency or pulsed magnetron sputtering (RFS or PMS), metal organic chemical vapor deposition (MOCVD), and plasma enhanced chemical vapor deposition (PECVD).

In some embodiments, the window layer 108, the absorber layer 104, or both layers may be deposited using the same deposition process. In some embodiments, the two layers are deposited by close-space sublimation (CSS), diffused transport deposition (DTD), sputtering, or vapor transport deposition (VTD). In particular embodiments, the two layers are deposited by sputtering. In some other embodiments, the window layer may be sputtered and the absorber layer may be deposited using CSS.

Incorporation of oxygen in the window layer 108, the absorber layer 104, or both may be employed during deposition. In some embodiments, the deposition is carried out in the presence of oxygen. An alternate method uses a source material containing oxygen to deposit a film or layer, in some other embodiments. Typically, particles or atoms are derived from the source material, and are deposited on a substrate or support to form a film. The source material may include an oxidation product of a semiconductor material, according to some embodiments of the invention. The amount of oxygen as described previously refers to the oxygen concentration present during deposition of a semiconductor layer, (for example, the window layer 108) or as-deposited layer, that is, before any post-deposition processing. Without being bound by any theory, it is observed that oxygen concentration in the semiconductor layer may change substantially during post-deposition processing (for example, thermal processing, CdCl₂ treatment) depending, in part, on the conditions of processing.

Moreover, CdTe deposition on CdS in the presence of oxygen may be desirable as oxygen at the CdTe/CdS interface may provide improved interface characteristics that may result in higher device efficiencies and enhanced device stability. Without being bound by any theory, it is believed that oxygen at the interface between the second semiconductor layer 104, and the third semiconductor layer 106 (for example, CdS/CdTe) provides improved interface properties (for example, reduce the lattice mismatch, lower pinhole density, or enhanced alloying among layer constituent elements), allowing for high minority carrier lifetimes at the interface in contact with the window layer.

In one embodiment, after the step of disposing the absorber layer 104, cadmium chloride (CdCl₂) treatment is carried out. A solution of CdCl₂ or CdCl₂ vapor may be used for the treatment. The treatment with CdCl₂ is known to increase the carrier lifetime of the absorber layer 104. The treatment with cadmium chloride may be followed by an etching or rinsing step. In one embodiment, etching may be carried out using a suitable acid or base, for example ethylene diamine (DAE), ammonium hydroxide etc. In other embodiments, the CdCl₂ may be rinsed off the surface, resulting in a stoichiometric cadmium telluride at the surface, mainly removing the cadmium oxide and residual CdCl₂ from the surface, leaving a cadmium-to-tellurium ratio of about 1 at the surface. The etching works by removing non-stoichiometric material that forms at the surface during processing. Other etching techniques known in the art that may result in a stoichiometric cadmium telluride at the surface may also be employed.

A layer may then be disposed on the cadmium chloride-treated absorber layer 104, wherein the layer comprises a metal or metalloid of Group 15. The step of disposing the layer includes depositing the layer by a suitable deposition technique followed by a thermal processing step. Suitable deposition techniques may include one or more of sputtering, evaporation deposition, chemical vapor deposition (CVD), vapor transport deposition, electrochemical deposition, and atomic layer deposition (ALD) depending on a target material used for the deposition, and various deposition conditions. In some instances, the layer is disposed by sputtering. In some instances, chemical vapor deposition or electrochemical bath deposition may be suitable deposition techniques.

The layer of metal or a metalloid of Group 15 may then be thermally processed in an oxygen environment. The thermal processing step can take place under any suitable condition. In one embodiment, the thermal processing step, for example, an annealing step, may be carried out in an environment comprising oxygen, for example in air. The annealing may be carried out under a suitable pressure between about 1 mTorr and about 760 Torr (1 atmosphere). In certain instances, the annealing pressure may range between about 1 Torr and 500 Torr. The layer may be annealed between about 400 degrees Celsius and about 700 degrees Celsius, and in certain instances, between about 450 degrees Celsius and about 550 degrees Celsius. The annealing may be carried out for a suitable duration, for example, about 1 minute to about 60 minutes. In certain instances, the annealing may be carried out for duration between about 2 minutes and about 30 minutes.

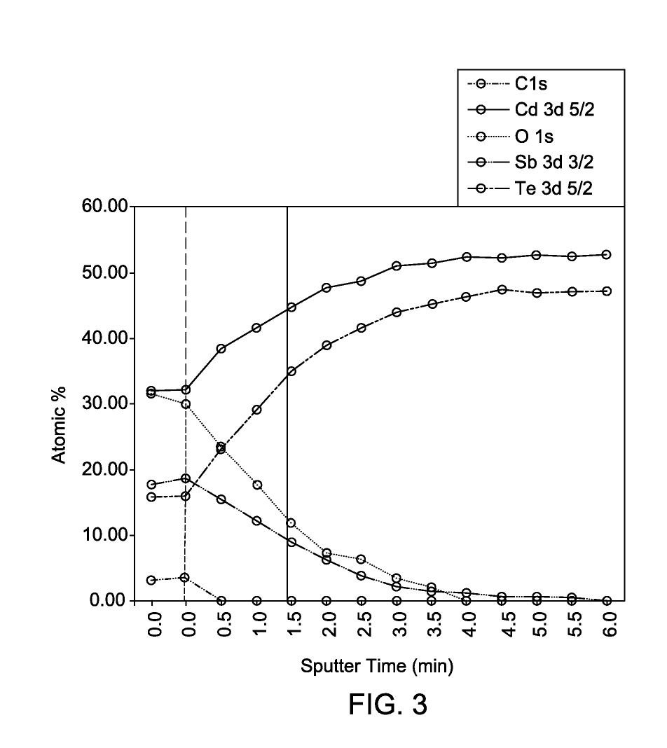

During the annealing step, recrystallization and chemical changes may occur in the layer, and the desired compounds (for example, an oxide and/or a complex oxide) can be formed. While not wishing to be bound by any theory, it was observed that the desired compounds, for example an oxide and/or a complex compound for the intermediate layer 102 were generally obtained upon thermal treatment of the deposited layer. For example, an antimony layer of about 60 nm thick was deposited on the absorber layer 104, which layer was then heated in air at about 500 degrees Celsius for about 5 minutes. FIG. 3 shows X-ray Photoelectron Spectroscopy (XPS) profiles of the antimony layer after annealing. The XPS graph clearly suggests the presence of antimony oxide (SbₓO_{y}) and the complex compound (for example, CdSbₓTe_{y}O_{z}).

In one embodiment, an oxide may be directly deposited by a suitable deposition technique, for example ALD. In some embodiments, a metal or metalloid of Group 15 may be deposited for example by sputtering in presence of high amount (more than about 5 volume percent) of oxygen as a process gas (that is, in an oxygen-containing environment) during the growth process. In these instances, the suitable deposition technique may be sputtering. In some instances, the deposition of the intermediate layer 102 may be performed in the presence of an amount of oxygen between about 5 volume percent to about 50 volume percent.

After the deposition of the intermediate layer 102, a second cycle of CdCl₂ treatment followed by surface rinsing/cleaning may again be performed, in some embodiments. The photovoltaic device 100 may be completed by depositing the back contact layer 106, for example, the metal layer (described previously) on the intermediate layer 102.

In some embodiments, other components (not shown) may be included in the photovoltaic device 100, such as, buss bars, external wiring, laser etches, etc. For example, when the device 100 forms a photovoltaic cell of the photovoltaic module, a plurality of photovoltaic cells may be connected in series, in parallel or both in order to achieve a desired voltage, such as through an electrical wiring connection. Each end of the connected cells may be attached to a suitable conductor such as a wire or bus bar, to direct the generated current to convenient locations for connection to a device or other system using the generated current. In some embodiments, a laser may be used to scribe the deposited layers of the photovoltaic device 100 to divide the device into a plurality of connected cells.

In some embodiments, a manufacturing method may include thermally processing multiple devices (for example, annealing of a compound-containing layer as discussed previously) in a face-to-face arrangement. The method may include thermally processing a first device assembly comprising a window layer, an absorber layer, and an intermediate layer disposed on the absorber layer, and thermally processing a second device assembly comprising a second window layer, a second absorber layer, and a second intermediate layer disposed on the second absorber layer. In one embodiment, the two assemblies are thermally processed simultaneously. The first and second assemblies are arranged such that the intermediate layers face each other with a gap between them during the thermal processing. In some other embodiments, the assemblies may be thermally processed one by one in stand-alone configuration.

In some instances, the manufacturing method further includes disposing at least one spacer between the intermediate layers, such that the layers are spaced apart from one another during the thermal processing. Generally speaking, any suitable spacer having the required structural characteristics capable of withstanding the thermal processing conditions (as described previously) may be used for separating the first assembly and the second assembly, and for maintaining a desired gap between the two assemblies.

### EXAMPLES

The examples that follow are merely illustrative, and should not be construed to be any sort of limitation on the scope of the claimed invention.

Comparative Sample 1: Cadmium telluride photovoltaic devices without an intermediate layer:

A cadmium telluride photovoltaic device was made by depositing several layers on a cadmium tin oxide (CTO) transparent conductive oxide (TCO)-coated substrate. The substrate was a 1.3 millimeters thick CIPV065 glass, which was coated with a CTO transparent conductive layer and a thin high resistance transparent zinc tin oxide (ZTO) buffer layer. The window layer was deposited on the ZTO layer.

Following the deposition of the CdS layer, a CdTe layer (about 3 micrometers thick) was deposited over the window layer using a close spaced sublimation process at a substrate temperature of about 550 degrees Celsius in an environment containing 1 Torr of Oxygen and 15 Torr of Helium. The resulting assembly was treated with cadmium chloride in solution and annealed at a temperature of about 370 degrees Celsius for about 40 minutes in air. At the end of the stipulated time, the CdCl₂ was rinsed off and the assembly was treated with a copper solution and subjected to annealing at a temperature of about 200 degrees Celsius for a duration of about 18 minutes. Gold was then deposited on the copper treated layer as the back contact by evaporation process.

Inventive Sample 1: Cadmium telluride photovoltaic devices having an intermediate layer with a Cu/Au back contact layer.

A cadmium telluride photovoltaic device was made by depositing several layers as explained in comparative example until the step of CdCl₂ treatment of the CdTe layer, except, this first CdCl₂ treatment was only done for 20 minutes. A 60 nm antimony layer was then deposited on the treated CdTe layer. The antimony layer was deposited by RF sputtering. The layer was then carried out for thermal annealing before depositing a back contact layer. Annealing was performed at atmospheric pressure in air for about 5 minutes. FIG. 3 shows X-ray Photoelectron Spectroscopy (XPS) profiles of the antimony layer after annealing. XPS profiles in FIG. 3 clearly indicate presence of antimony oxide and complex compound CdTexSbyOz. The resulting assembly was again treated with cadmium chloride (CdCl₂) in solution and annealed at a temperature of about 370 degrees Celsius for about 20 minutes in air. The CdCl₂ was rinsed off. The assembly was then treated with a copper solution and subjected to annealing at a temperature of about 200 degrees Celsius for duration of about 18 minutes. Gold was then deposited on the copper treated layer as the back contact by evaporation process.

Inventive Sample 2: Cadmium telluride photovoltaic devices having an intermediate layer with a Cu/Mo/Al back contact layer.

As explained in above examples, a cadmium telluride photovoltaic device was deposited until the step of the deposition of the CdTe layer. Unlike above examples, no CdCl₂ treatment was performed after the deposition of CdTe layer. A 60 nm antimony layer was then deposited on the untreated CdTe layer. The antimony layer was deposited by RF sputtering. The layer was then carried out for thermal annealing before depositing a back contact layer. Annealing was performed at atmospheric pressure in air for about 5 minutes. The resulting assembly was then treated with cadmium chloride (CdCl₂) in solution and annealed at a temperature of about 400 degrees Celsius for about 20 minutes in air. The CdCl₂ was rinsed off. The assembly was then treated with a copper solution and subjected to annealing at a temperature of about 200 degrees Celsius for duration of about 18 minutes. Mo/Al was then deposited on the copper treated layer as the back contact by evaporation process.

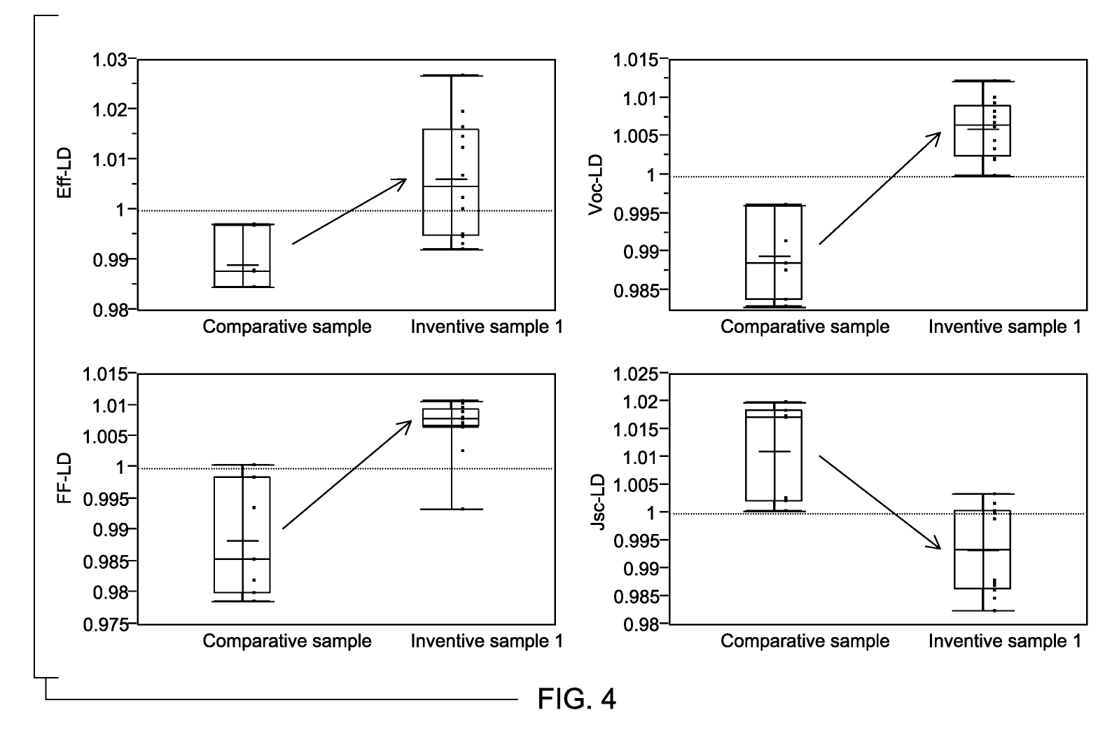

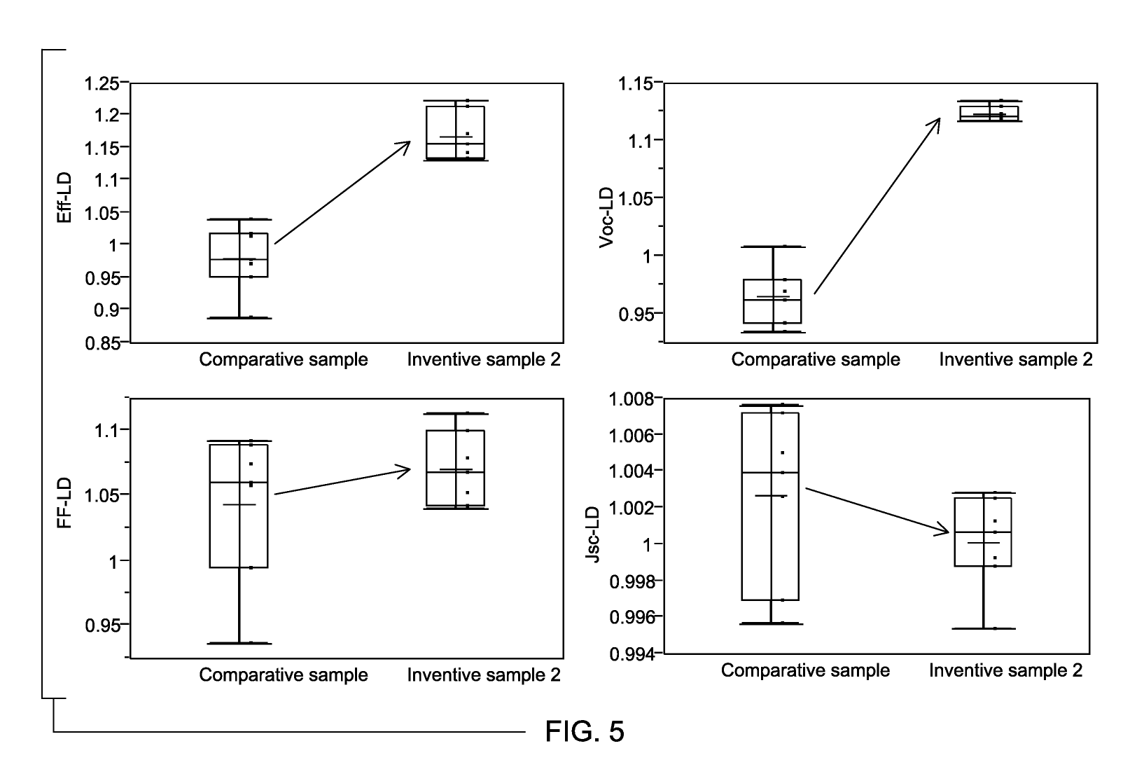

As illustrated in FIGS. 4 and 5, the device performance parameters—efficiency (Eff), FF (fill factor), V_{oc} (open circuit voltage), and J_{sc} (current density) show improvement for the Inventive samples 1 and 2 as compared to the comparative sample. More particularly, each of the inventive samples 1 and 2 shows improved V_{oc}, FF, and efficiency of the device.

The appended claims are intended to claim the invention as broadly as it has been conceived and the examples herein presented are illustrative of selected embodiments from a manifold of all possible embodiments. Accordingly, it is the Applicants' intention that the appended claims are not to be limited by the choice of examples utilized to illustrate features of the present invention. As used in the claims, the word “comprises” and its grammatical variants logically also subtend and include phrases of varying and differing extent such as for example, but not limited thereto, “consisting essentially of” and “consisting of.” Where necessary, ranges have been supplied; those ranges are inclusive of all sub-ranges there between. It is to be expected that variations in these ranges will suggest themselves to a practitioner having ordinary skill in the art and where not already dedicated to the public, those variations should where possible be construed to be covered by the appended claims. It is also anticipated that advances in science and technology will make equivalents and substitutions possible that are not now contemplated by reason of the imprecision of language and these variations should also be construed where possible to be covered by the appended claims.

1. A device comprising an intermediate layer disposed between an absorber layer and a back contact layer, wherein the intermediate layer comprises a metal or a metalloid of Group 15 and oxygen.

2. The device of claim 1, wherein the metalloid of Group 15 comprises antimony.

3. The device of claim 1, wherein the intermediate layer has a band gap greater than the band gap of the absorber layer.

4. The device of claim 1, wherein the intermediate layer comprises an oxide.

5. The device of claim 1, wherein the intermediate layer has an average thickness in a range from about 10 nanometers to about 100 nanometers.

6. The device of claim 1, further comprising a window layer disposed on the absorber layer opposite to the intermediate layer.

7. The device of claim 6, wherein the window layer comprises sulfur, oxygen, selenium, or combinations thereof.

8. The device of claim 7, wherein the window layer comprises cadmium sulfide, zinc sulfide, indium sulfide, cadmium selenide, zinc selenide, indium selenide, cadmium sulfate, cadmium oxysulfate, zinc sulfate, zinc oxysulfate, or a combination thereof.

9. The device of claim 1, wherein the absorber layer comprises a semiconductor material selected from the group consisting of cadmium telluride, cadmium zinc telluride, cadmium sulfur telluride, cadmium selenium telluride, cadmium lead telluride, cadmium manganese telluride, cadmium magnesium telluride, and combinations thereof.

10. The device of claim 1, further comprising an electrically conductive layer disposed on the window layer.

11. The device of claim 10, wherein the electrically conductive layer comprises cadmium tin oxide, indium tin oxide, zinc tin oxide, fluorine-doped tin oxide, indium-doped cadmium oxide, aluminum-doped zinc oxide, indium zinc oxide, or combinations thereof.

12. The device of claim 1, wherein the back contact layer comprises gold, platinum, molybdenum, aluminum, chromium, nickel, copper, silver, antimony, tellurium, graphite, or a combination thereof.

13. The device of claim 6, wherein the window layer, the absorber layer, or both layers further comprise oxygen.

14. A photovoltaic module comprising a plurality of devices as defined in claim 1.

15. A photovoltaic device, comprising:
a window layer comprises cadmium sulfide,
an absorber layer comprises cadmium telluride disposed on the window layer,
an intermediate layer comprising a metal or a metalloid of Group 15 and oxygen, disposed on the absorber layer; and
a back contact layer disposed on the intermediate layer.

16. A method, comprising:
disposing an intermediate layer on an absorber layer, wherein the intermediate layer comprises a metal or metalloid of Group 15, and
thermal processing the intermediate layer in an oxygen environment.

17. The method of claim 16, wherein disposing the intermediate layer comprises depositing the layer by sputtering, evaporation deposition, CVD, vapor transport deposition, or atomic layer deposition.

18. The method of claim 16, wherein disposing the intermediate layer comprises disposing a layer of antimony, arsenic, bismuth, or a combination thereof.

19. The method of claim 16, wherein thermal processing the intermediate layer comprises heating the layer in an oxygen environment.

20. The method of claim 16, wherein thermal processing the intermediate layer comprises heating the layer at a temperature in a range between about 400 degrees Celsius and about 700 degrees Celsius.

21. The method of claim 16, wherein thermal processing the intermediate layer comprises heating the layer for a duration of about 1 mins to about 10 mins.
